(19) United States
(12) Patent Application Publication
(10) Pub. No.: US 2024/0405012 A1
(43) Pub. Date: Dec. 5, 2024

(54) RESISTOR-DIODE LADDER, ESD PROTECTION CIRCUIT INCLUDING SAME, SEMICONDUCTOR DEVICE INCLUDING SAME, AND METHOD OF MANUFACTURING SAME

(71) Applicant: TAIWAN SEMICONDUCTOR MANUFACTURING COMPANY, LTD., Hsinchu (TW)

(72) Inventors: Li-Wei ChU, Hsinchu (TW); Jam-Wem LEE, Hsinchu (TW); Wun-Jie LIN, Hsinchu (TW); Shou Ming LIU, Hsinchu (TW)

(21) Appl. No.: 18/505,274

(22) Filed: Nov. 9, 2023

Related U.S. Application Data
(60) Provisional application No. 63/505,426, filed on May 31, 2023.

(51) Int. Cl. H01L 27/02; H01L 23/528; H01L 29/66

(52) U.S. Cl. CPC H01L 27/0255; H01L 23/528; H01L 27/0288; H01L 29/6609

(57) ABSTRACT

An electrostatic discharge (ESD) protection cell region (of a semiconductor device) includes a resistor-diode ladder and a power clamp circuit coupled in parallel between a first power rail PR1 and a second power rail PR2. The resistor-diode ladder is also coupled between an input/output (I/O) pad of the semiconductor device and core circuitry of the semiconductor device. The resistor-diode ladder includes: a first diode coupled between a first node and the first power rail; a first resistor coupled between the first node and a second node; a second diode coupled between the second node and the first power rail; a third diode coupled between the first node and the second power rail; and a fourth diode coupled between the second node and the second power rail. The first node is coupled to the I/O pad. The resistor-diode ladder is coupled between the I/O pad and the core circuitry.

### PRIORITY

The present application claims the priority of U.S. Provisional Application No. 63/506,426, filed May 31, 2023, which is incorporated herein by reference in its entirety.

### BACKGROUND

The integrated circuit (IC) industry produces a wide variety of analog and digital semiconductor devices to address issues in a number of different areas. Developments in semiconductor process technology nodes have progressively reduced component sizes and tightened spacing resulting in progressively smaller transistor sizes and correspondingly increased transistor densities. As they have become smaller, transistors have become increasingly more susceptible to damage from electrostatic discharge (ESD).

To protect core circuity of a semiconductor device against electrostatic discharge (ESD), an input/output (I/O) architecture of the semiconductor device is provided with an ESD protection (ESDP) circuit.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1A-1D are corresponding circuit diagrams, in accordance with some embodiments.

FIGS. 2A-2H are corresponding layout diagrams, in accordance with some embodiments.

FIGS. 3A-3B are corresponding layout diagrams, in accordance with some embodiments.

FIG. 3C is a cross-sectional diagram, in accordance with some embodiments.

FIGS. 3D-3E are corresponding cross-sectional views, in accordance with some embodiments.

FIGS. 4-5 are flowcharts of corresponding methods of manufacturing a semiconductor device, in accordance with some embodiments.

FIG. 6 is a block diagram of an electronic design automation (EDA) system in accordance with some embodiments.

FIG. 7 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above.” “upper” and the like, are used herein for case of description to describe one element or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, an electrostatic discharge (ESD) protection (ESDP) cell region (of a semiconductor device) includes a resistor-diode ladder and a power clamp circuit coupled in parallel between a first power rail PR1 (e.g., having VDD) and a second power rail PR2 (e.g., having VSS). The resistor-diode ladder is also coupled between an input/output (I/O) pad of the semiconductor device and core circuitry of the semiconductor device. In some embodiments, the resistor-diode ladder (e.g., 104A) includes: a first diode D2(0) coupled between a first node and first power rail PR1; a first resistor R0 coupled between the first node and a second node; a second diode D2(1) coupled between the second node and first power rail PR1; a third diode D1(0) coupled between the first node and second power rail PR2; and a fourth diode D1(1) coupled between the second node and second power rail PR2. The first node is coupled to the I/O pad. The resistor-diode ladder is coupled between the I/O pad and the core circuitry.

According to another approach for a counterpart ESDP circuit: in place of the combination of diodes D2(0) and D2(1) and resistor R0 as in some embodiments, a larger first single diode is used; and, in place of the combination of diodes D1(0) and D1(1) and resistor RO as in some embodiments, a larger second single diode is used. For a given value of the capacitance of the larger first and second single diodes according to the other approach, signal loss is proportional to frequency. The larger first and second single diodes according to the other approach exhibit parasitic capacitances that are sufficiently large to cause significant signal loss at high frequencies. When coupled in parallel to a counterpart power clamp, the larger first and second single diodes according to the other approach also exhibit a clamping voltage, Vclamp, that is sufficiently large to result in a correspondingly large leakage current to the counterpart core circuity, which is potentially harmful to the counterpart core circuitry. Replacing the larger first and second single diodes according to the other approach with a resistor-diode ladder according to some embodiments, e.g., resistor-ladder 104A, such embodiments reduce parasitic capacitance while also reducing clamping voltage Vclamp. The reduced parasitic capacitance of such embodiments reduces signal loss as compared to the other approach. The decreased clamping voltage Vclamp of such embodiments results in a lower leakage current to the core circuitry as compared to the other approach. In some embodiments, the parasitic capacitance experienced by such embodiments is reduced by about 21.3% as compared to the other approach. In some embodiments, clamping voltage Vclamp is reduced by about 24.4% as compared to the other approach.

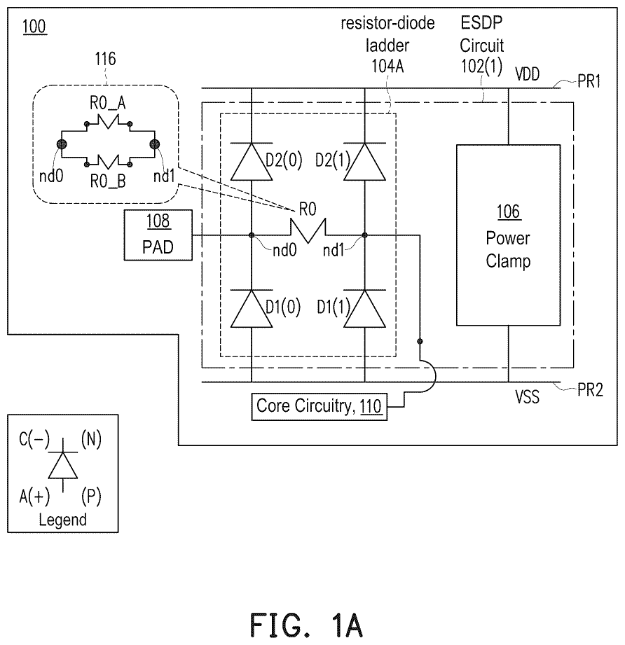

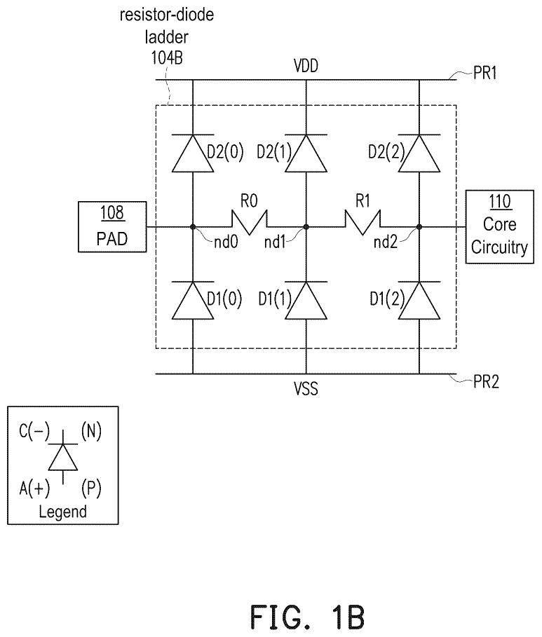

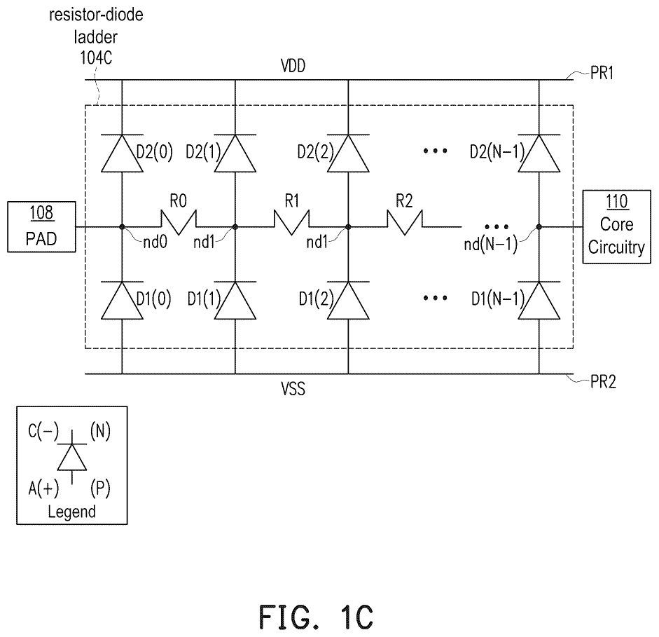

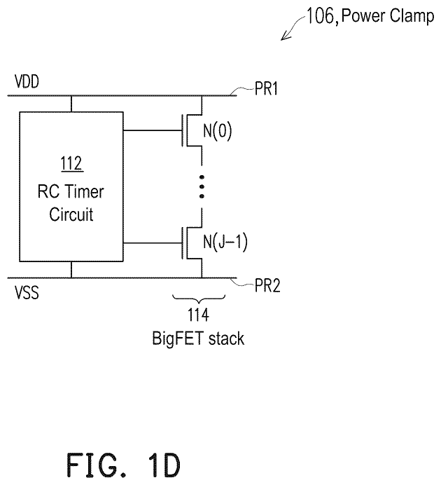

FIG. 1A is a circuit diagram of an ESDP circuit 102(1) of a semiconductor device 100, in accordance with some embodiments.

ESDP circuit 102(1) includes a resistor-diode ladder 104A and a power clamp circuit 106 (FIG. 1D) coupled in parallel between a power rail PR1 and a power rail PR2 of semiconductor device 100. Power rail PR1 has a first reference voltage, e.g., VDD, and power rail PR2 has a second reference voltage, e.g., VSS, different than the first reference voltage. In some embodiments, the first and second reference voltages are values other than correspondingly VDD and VSS. Resistor-diode ladder 104A is also coupled between an input/output (I/O) pad 108 of semiconductor device 100 and core circuitry 110 of semiconductor device 100.

In FIG. 1A, resistor-diode ladder 104A includes: a diode D2(0) coupled between a first node nd0 at the anode and power rail PR1 at the cathode; a diode D1(0) coupled between first node nd0 at the cathode and power rail PR2 at the anode; a first resistor R0 coupled between first node nd0 and a second node nd1; a second diode D2(1) coupled between second node nd1 at the anode and power rail PR1 at the cathode; and a fourth diode D1(1) coupled between second node nd1 at the cathode and power rail PR2 at the anode. Diode D2(0) is larger than diode D2(1). Diode D1(0) is larger than diode D1(1).

In some embodiments, resistor-diode ladder 104A is described as a four-terminal network because resistor-diode ladder 104A is coupled to each of power rail PR1, power rail PR2, I/O pad 108 and core circuitry 110. Similarly, in some embodiments, because ESDP circuit 102(1) includes resistor-diode ladder 104A, ESDP circuit 102(1) is described as a four-terminal network because resistor-diode ladder 104A is coupled to each of power rail PR1, power rail PR2, I/O pad 108 and core circuitry 110.

In FIG. 1A, each of diodes D2(0), D2(1), D1(0) and D1(1) has a corresponding size, e.g., in terms width and length, e.g., width/length. In FIG. 1A, diodes D2(0) and D1(0) are substantially the same size. In some embodiments, diodes D2(0) and D1(0) are substantially different sizes.

In some embodiments, a ratio of the sizes of diodes D2(0) and D2(1) is substantially SR, and a ratio of the sizes of diodes D1(0) and D1(1) is also substantially SR, where SR is a variable having positive real values in a range as follows: (≈9.0)≤SR≤(≈1.0). In some embodiments, SR is in a range as follows: (≈6.0)≤SR≤(≈4.0). In some embodiments, SR≈(8.5/1.5).

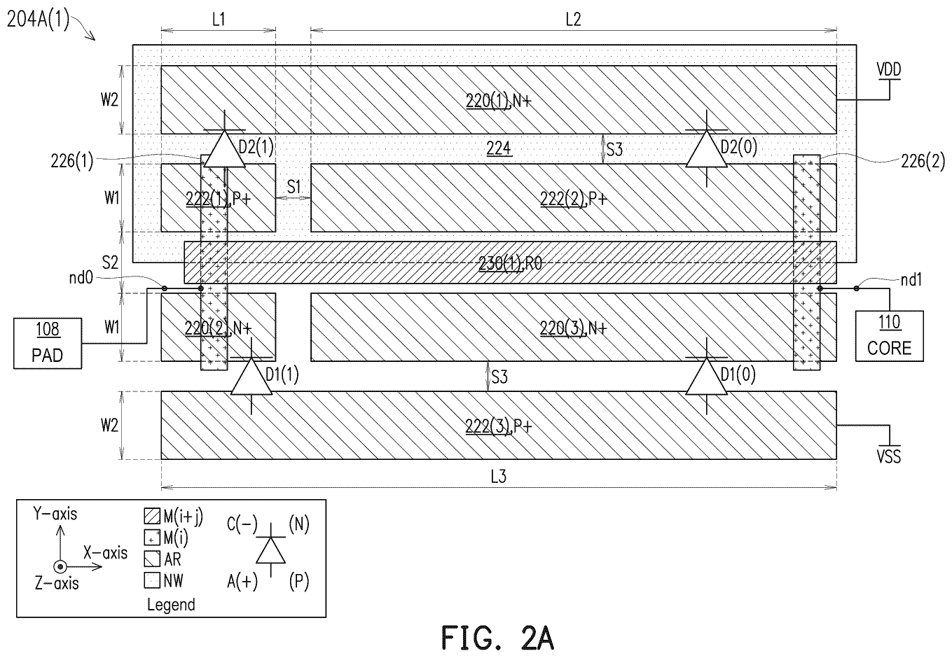

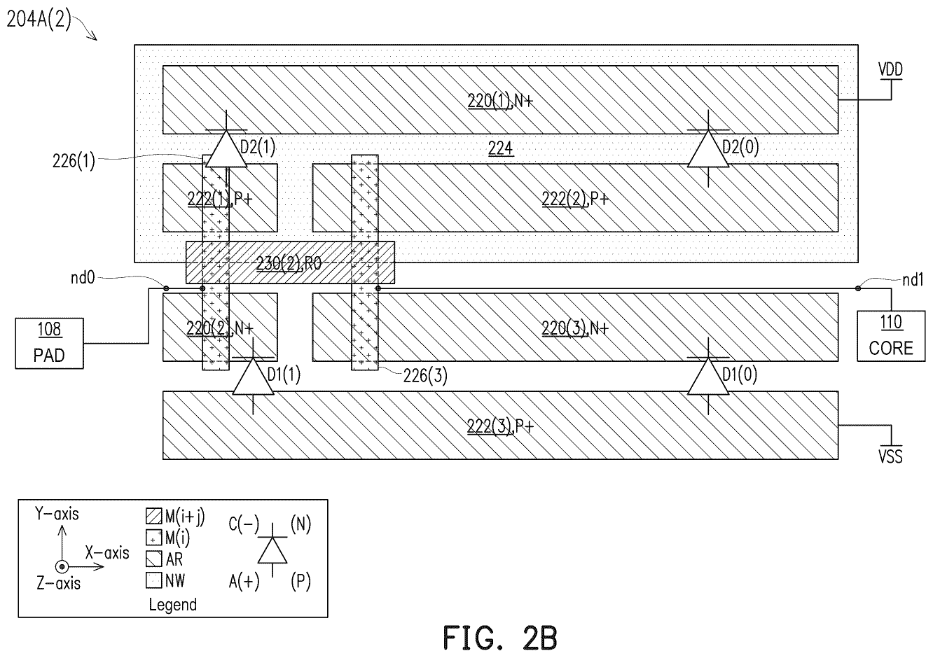

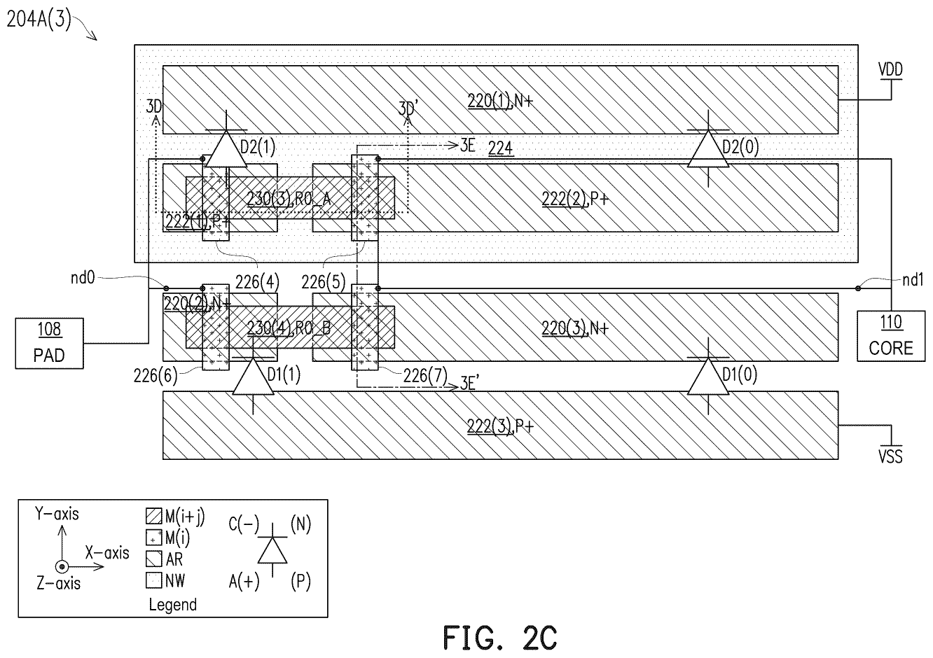

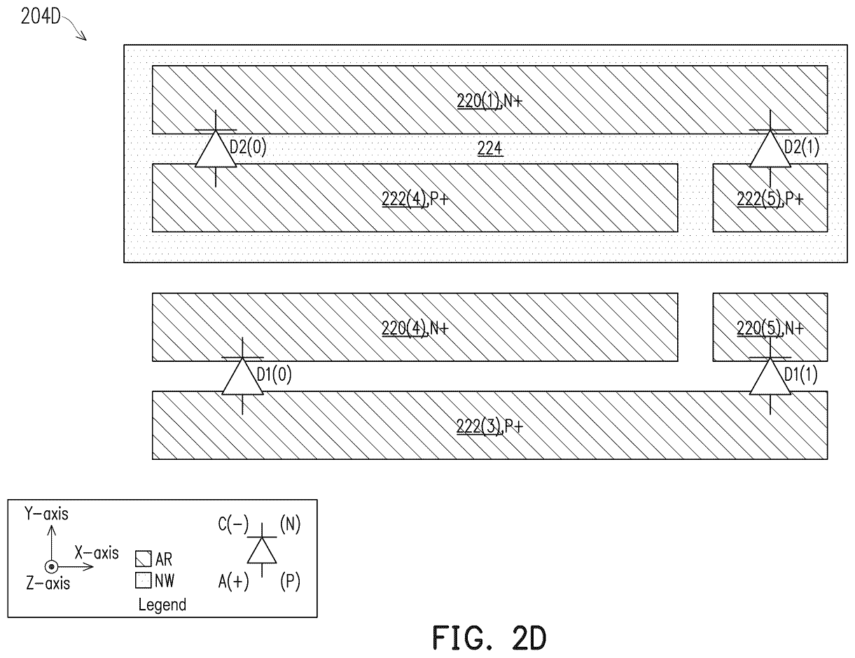

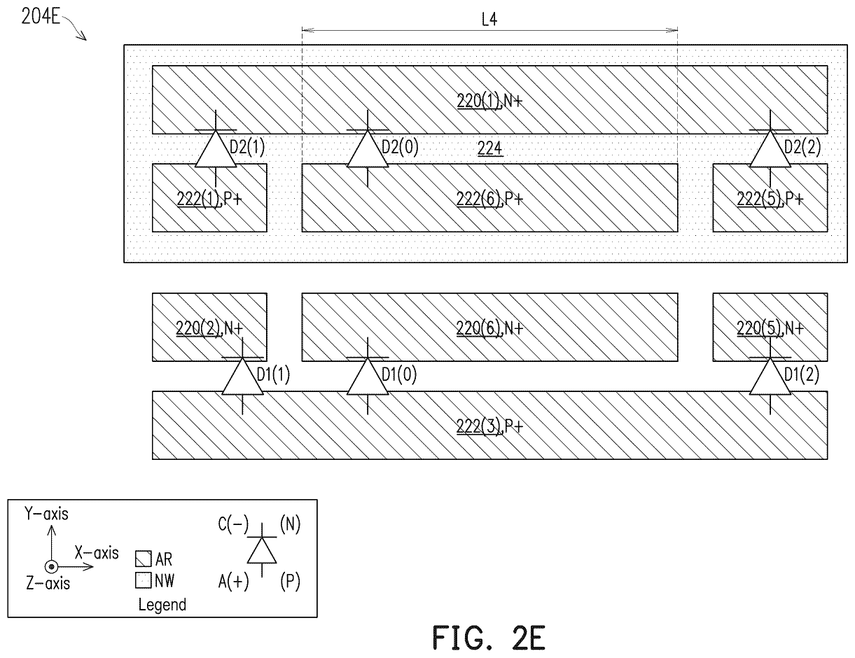

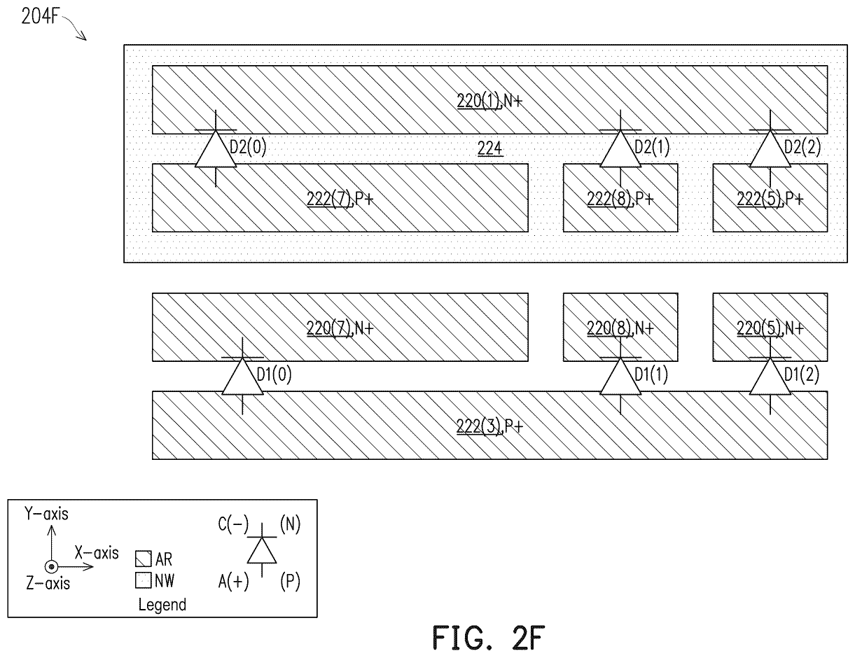

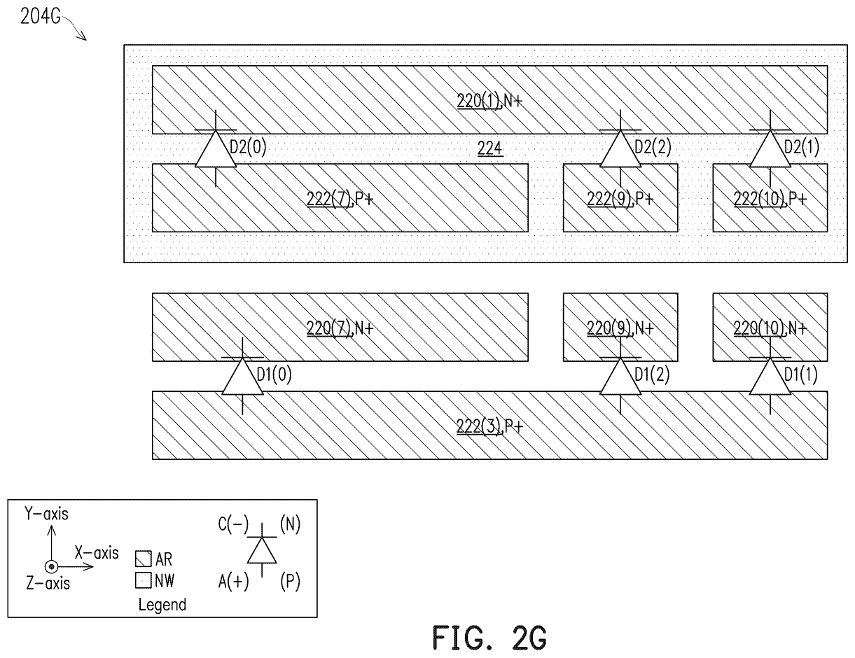

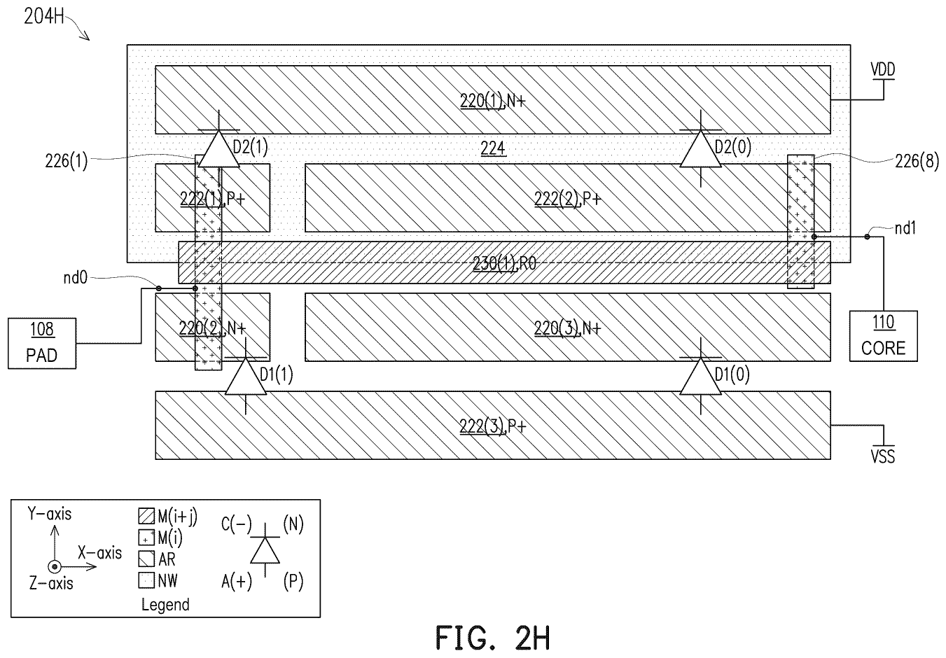

In some embodiments, (≈0.1 ohms)≤R0≤(≈5.0 ohms). In some embodiments, resistor R0 is represented by resistors coupled in parallel between nodes nd0 and nd1. As shown in an exploded view 116 in FIG. 1A, in some embodiments, resistor R0 is represented by resistors R0_A and R0_B coupled in parallel between nodes nd0 and nd1 (FIG. 2C). In some embodiments, R0_A≈R0_B.

In some embodiments, one of diodes D2(0), D2(1), D1(0) and D1(1) is omitted. For example, in some embodiments, diode D1(1) is omitted (FIG. 2H). In such embodiments, a first number representing a total of the diodes (e.g., D1(0) and D1(1)) coupled to power rail PRI is different than a second number representing a total of the one or more diodes (e.g., D1(0)) coupled to power rail PR2.

FIG. 1B is a circuit diagram of a resistor-diode ladder 104B, in accordance with some embodiments.

Resistor-diode ladder 104B of FIG. 1B is similar to resistor-diode ladder 104A of FIG. 1A. For brevity, the discussion will focus on differences of resistor-diode ladder 104B as compared to resistor-diode ladder 104A rather than on similarities.

As compared to resistor-diode ladder 104A, resistor-diode ladder 104B further includes: a second resistor R1 coupled between node nd1 and a node nd2; a diode D2(2) coupled between node nd2 at the anode and power rail PR1 at the cathode; and a diode D1(2) coupled between node nd2 and second power rail PR2.

In resistor-diode ladder 104B, node nd2 is coupled to core circuitry 110 whereas node nd1 is coupled to core circuity 110 in resistor-diode ladder 104A. In some embodiments, diode D2(1) is larger than diode D2(2). In some embodiments, diode D1(1) is larger than diode D1(2). In some embodiments, D2(2)≈D2(1). In some embodiments, D1(2)≈D1(1).

FIG. 1C is a circuit diagram of a resistor-diode ladder 104C, in accordance with some embodiments.

Resistor-diode ladder 104C of FIG. 1C is similar to resistor-diode ladder 104B of FIG. 1B. For brevity, the discussion will focus on differences of resistor-diode ladder 104C as compared to resistor-diode ladder 104B rather than on similarities.

As compared to resistor-diode ladder 104B, resistor-diode ladder 104C further includes: a third resistor R2 coupled between node nd2 and a node nd(N−1), where N is a positive integer and 4≤N; a diode D2(N−1) coupled between node nd(N−1) at the anode and power rail PR1 at the cathode; and a diode D1(N−1) coupled between node nd(N−1) and second power rail PR2.

In resistor-diode ladder 104C, node nd (N−1) is coupled to core circuitry 110 whereas node nd2 is coupled to core circuity 110 in resistor-diode ladder 104B. In some embodiments, diode D2(2) is larger than diode D2(N−1)). In some embodiments, diode D1(2) is larger than diode D1(N−1). In some embodiments, D2(N−1)≈D2(2). In some embodiments, D1(N−1))≈D1(2).

FIG. 1D is a circuit diagram of a power clamp 106, in accordance with some embodiments.

Power claim 106 includes a resistor-capacitor (RC) timer circuit 112 and stack 114 of big field-effect transistors (FETs). In some embodiments, a big FET is referred to as a BigFET. In some embodiments, a BigFET is an FET having a large current-conducting capacity as compared to the current-conducting capacity of a typical FET. Typically, an FET having a large current-conducting capacity is a relatively big/large FET as compared to the size of a typical FET.

BigFET stack 114 includes one or more N-type FETs (NFETs) N(0) to N(J−1) coupled in series between power rail PR1 and power rail PR2, where J is a positive integer and 2≤ J. Outputs of RC timer circuit are correspondingly coupled to the gates of NFETs N(0)−N(J−1). In some embodiments, BigFET stack 114 is replaced by a single NFET coupled between power rail PRI and power rail PR2. In some embodiments, BigFET stack 114 is replaced by a single NFET coupled in series with an impedance element (not shown) between power rail PR1 and power rail PR2.

FIGS. 2A-2H are corresponding layout diagrams, in accordance with some embodiments.

The layout diagrams of FIGS. 2A-2H are representative of corresponding resistor-diode ladder regions of semiconductor devices. In each layout diagram, structures of the semiconductor device are represented by patterns (also known as shapes). For simplicity of discussion, elements in the layout diagram of FIGS. 2A-2B (and also in other layout diagrams disclosed herein) will be referred to as if they are structures rather than patterns per se. For example, pattern 220(1) in FIG. 2A represents an active region/area having N+ doping. In the following discussion, clement 220(1) is referred to as an N+ active region rather than as an N+ active area pattern.

In FIGS. 2A-2H, as well as in other layout diagrams disclosed herein, an orthogonal Cartesian coordinate system is assumed in which a first direction is parallel to the X-axis, a second direction is parallel to the Y-axis and a third direction is parallel to the Z-axis. A layout diagram per se is a top view. Shapes in the layout diagram are two-dimensional relative to, e.g., the X-axis and the Y-axis, whereas the device being represented is three-dimensional.

Typically, relative to the Z-axis, a semiconductor device is organized as a stack of layers in which are located corresponding structures, i.e., to which belong corresponding structures. Each shape in the layout diagram represents, more particularly, a component in a corresponding layer of the corresponding device. Regarding depth, i.e., positions along the Z-axis, the layout diagram typically represents relative depth, i.e., positions along the Z-axis, of shapes and corresponding layers by superimposing a second shape on a first shape so that the second shape at least partially overlaps the first shape.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding semiconductor device are represented, i.e., selected layers of the layout diagram are omitted, e.g., for simplicity of illustration. Alternatively, and/or additionally, in some circumstances, not all structures of the corresponding semiconductor device in a given layer, i.e., selected structures in the given layer of the layout diagram are omitted, e.g., for simplicity of illustration.

FIGS. 2A-2H, as well as in other layout diagrams disclosed herein, are examples of layout diagrams in which selected layers, and selected structures of layers, have been omitted. Regarding FIGS. 2A-2H, for example, active regions of a corresponding first layer are shown but structures of the first layer are omitted. Examples structures omitted from the first layer in FIGS. 2A-2H include metal-to-drain/source (MD) contact structures over corresponding portions of the active regions, or the like, for simplicity of illustration. Examples of layers omitted from FIGS. 2A-2H include selected layers of metallization and layers of interconnection (the latter including via contact structures), or the like, for simplicity of illustration.

In FIG. 2A, resistor-diode ladder region 204A(1) is an example of resistor-diode ladder 104A of FIG. 1A.

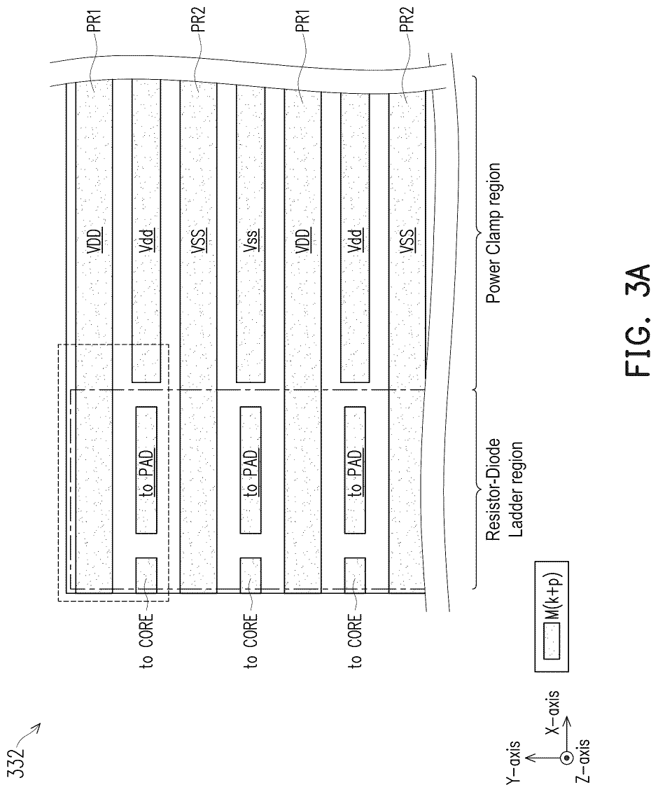

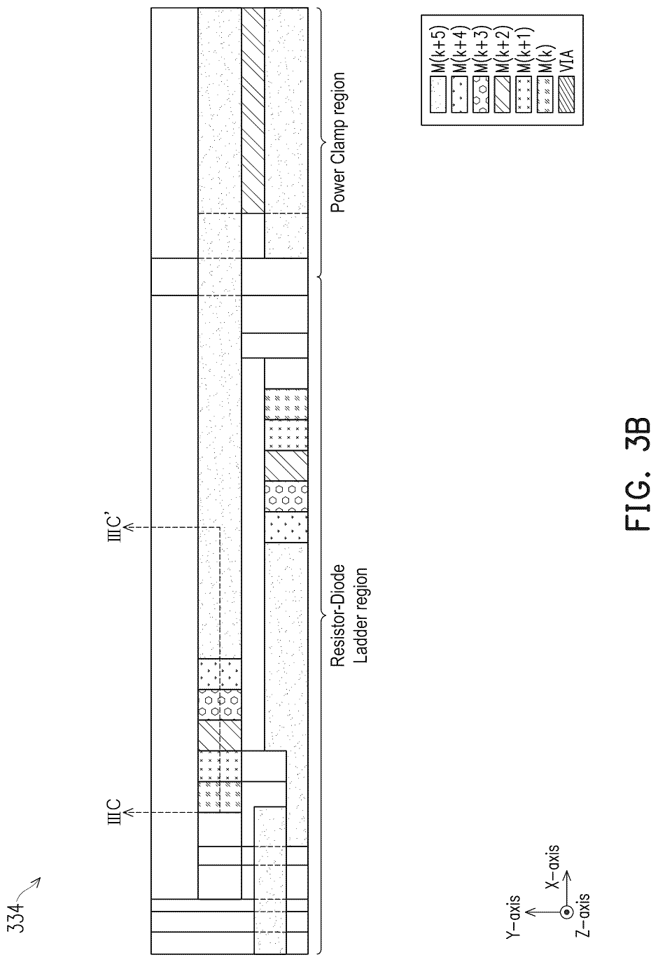

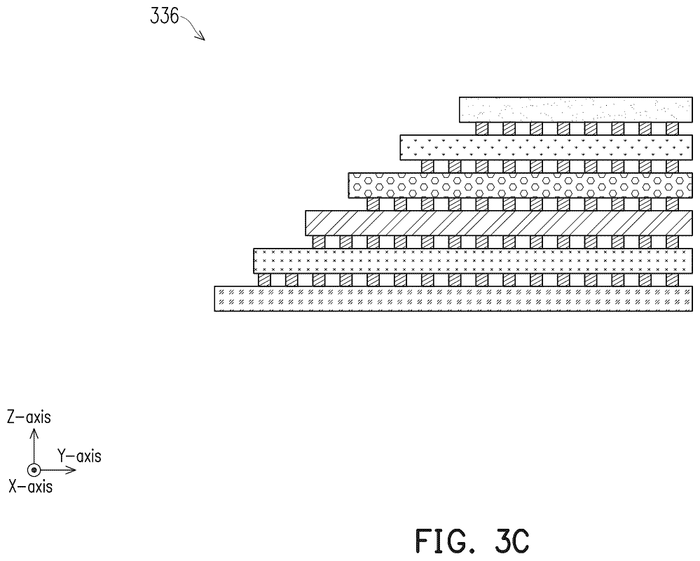

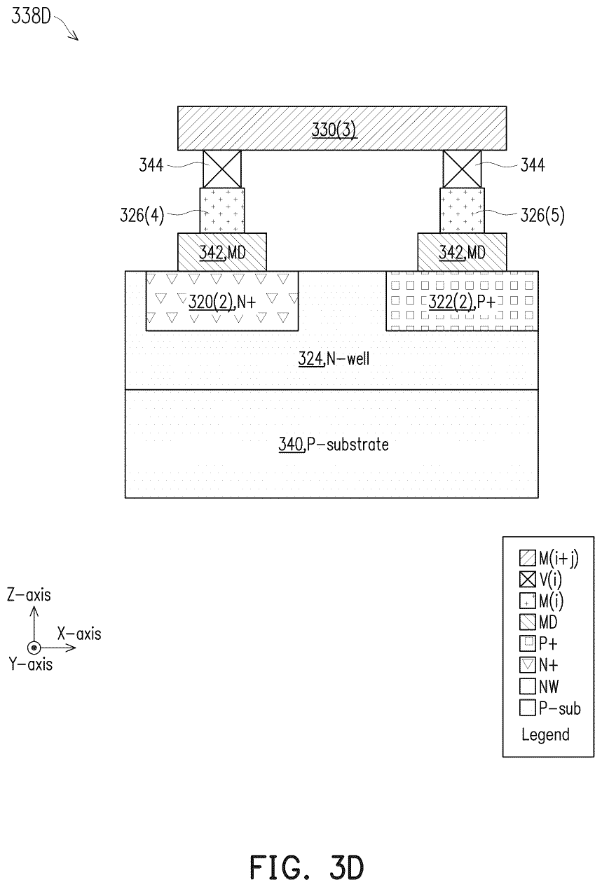

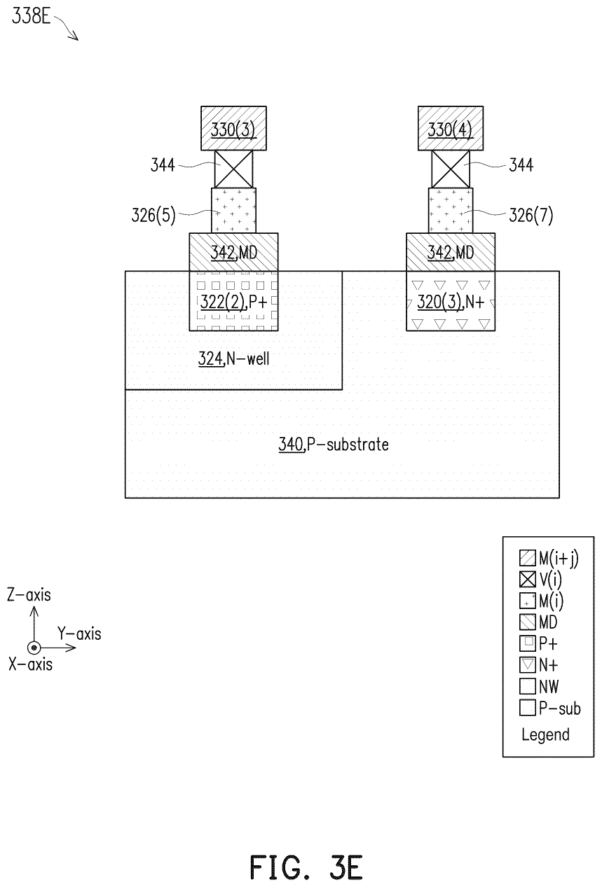

Resistor-diode ladder region 204A(1) includes an N-well and active regions 220(1)-220(3), and active regions 222(1)-222(3) that are formed in a semiconductor substrate (e.g., P-type substrate 230 FIGS. 3D-3E) and extend in a direction parallel to the X-axis. Well region 224 is configured (e.g., doped or implanted) with a first dopant-type, e.g., an N-type dopant (or impurity).

Active regions 220(1)-220(3) are configured (e.g., doped or implanted) with the N-type dopant at concentrations sufficiently high/large so that active regions 220(1)-220(3) function as cathodes of corresponding diodes (discussed below). Active regions 222(1)-222(3) are configured with a second dopant type, e.g., a P-type dopant different than the first dopant, at concentrations sufficiently high/large so that active regions 222(1)-222(3) function as anodes of corresponding diodes (discussed below). In some embodiments, active regions 220(1)-220(3) are configured with a P-type dopant to function as anodes of corresponding diodes and active regions 222(1)-222(3) are configured with an N-type dopant to function as cathodes of corresponding diodes. Hereinafter, active regions such as active regions 220(1)-220(3) are referred to as N+ (or N-plus) active regions, and active regions such as active regions 222(1)-222(3) are referred to as P+ (or P-plus) active regions. N+ active region 220(1) and P+ active regions 222(1) and 222(2) are in N-well 224.

In FIG. 2A, N+ active regions 220(2) and 220(3) are substantially coaxially aligned. P+ active regions 222(1) and 222(2) are substantially coaxially aligned. Relative to the X-axis: left and right ends of N+ active region 220(3) are correspondingly proximal and distal to N+ active region 220(2); and left and right ends of P+ active region 222(2) are correspondingly proximal and distal to P+ active region 222(1).

Relative to the X-axis, N+ active regions 220(2) and 220(3) are separated from each other by a gap S1. P+ active regions 222(1) and 222(2) are separated from each other by gap S1. Relative to the Y-axis: N+ active regions 220(2) and 220(3) are separated correspondingly from P+ active regions 222(1) and 222(2) are by a gap S2; N+ active region 220(1) is separated from each of P+ active regions 222(1) and 222(2) by a gap S3; and each of N+ active regions 220(2) and 220(3) is separated from P+ active region 222(3) by gap S3.

In FIG. 2A, S2≤S3≤S1. In some embodiments, 0<S2≤(≈0.60 micrometers (μm)). In some embodiments, 0<S3≤(≈0.75 μm). In some embodiments, 0<S1≤(≈2.00 μm).

Relative to the X-axis, each of N+ active region 220(2) and P+ active region 222(1) has a length L1; each of N+ active region 220(3) and P+ active region 222(2) has a length L2; and each of N+ active region 220(1) and P+ active region 222(3) has a length L3.

In FIG. 2A, L1≤L2≤L3. In some embodiments, 0<L1≤(≈10.00 μm). In some embodiments, 0<L2≤(≈30.00 μm). In some embodiments, 0<L3≤(≈40.00 μm).

Relative to the Y-axis: each of N+ active regions 220(2) and 220(3) and P+ active regions 222(1) and 222(2) has a width W1; and each of N+ active region 220(1) and P+ active region 222(3) has a width W2. In FIG. 2A, W1≈W2. In some embodiments, 0<W1≤(≈9.00 μm). In some embodiments, 0<W2≤(≈9.00 μm).

In FIG. 2A, P+ active region 222(2) and a corresponding overlapping portion of N+ active region 220(1) correspondingly represent an anode and a cathode of a first diode D2(0) that includes a first PN junction. P+ active region 222(1) and a corresponding overlapping portion of N+ active region 220(1) correspondingly represent an anode and a cathode of a second diode D2(1) that includes a second PN junction. N+ active region 220(1) is coupled to VDD through power rail PR1. As a length of overlap between P+ active region 22(2) and N+ active region 220(1) is greater than a length of overlap between P+active region 222(1) and N+ active region 220(1), diode D2(0) is larger than diode D2(1).

In FIG. 2A, N+ active region 220(3) and a corresponding overlapping portion of the P+ active region 222(3) correspondingly represent a cathode and an anode of a third diode D1(0) that includes a third PN junction. N+ active region 220(2) and a corresponding overlapping portion of a P+ active region 222(3) correspondingly represent a cathode and an anode of a fourth diode D1(1) that includes a fourth PN junction. P+ active region 222(3) is coupled to VSS through power rail PR2. As a length of overlap between N+ active region 220(3) and P+ active region 222(3) is greater than a length of overlap between N+ active region 220(2) and P+ active region 222(3), diode D1(0) is larger than diode D1(1).

In FIG. 2A, P+active region 222(1) is coupled to N+ active region 220(2) by a conductive path that includes a segment 226(1) of a metallization layer k (M(k), where k is a non-negative integer. Segment 226(1) overlaps each of P+ active region 222(1) and N+ active region 220(2).

In some embodiments, M(k) is the first layer of metallization over the active regions. M(k) segment 226(1) is coupled to node nd0 (FIG. 1A), and node nd0 is coupled to I/O pad 108 (FIG. 1A). Hence, P+ active region 222(1) and N+ active region 220(2) are coupled to node nd0.

In FIGS. 2A-2H, and more generally for the present disclosure, a numbering convention is assumed in which a first metallization layer is layer zero (M0). A first layer of interconnection over layer M0 is referred to as layer VIA0. In some embodiments, depending upon the numbering convention of the corresponding process node by which a semiconductor device is manufactured, the first layer of metallization layer is M1, and the first layer of interconnection over layer M1 is VIA1. Accordingly, as the first layer of metallization, the present disclosure assumes that M(k) is M0. In some embodiments, M(k) is a metallization layer above M0.

In FIG. 2A, P+ active region 222(2) is coupled to N+ active region 220(3) by a conductive path that includes an M(k) segment 226(2). M(k) segment 226(2) overlaps a right end of each of P+ active region 222(2) and N+ active region 220(3).

M(k) segment 226(2) is coupled to node nd1 (FIG. 1A), and node nd1 is coupled to core circuitry 110 (FIG. 1A). Hence, P+ active region 222(2) and N+ active region 220(3) are coupled to node nd1. In some embodiments, P+ active region 222(2) is coupled to node nd1 but N+ active region 220(3) is not coupled to node nd1.

In FIG. 2A, M(k) segments 226(1) and 226(2) are coupled together by a conductive path that includes a segment 230(1) of a metallization layer k+j (M(k+j), where layer M(k+j) is above layer M(k), and where j is a positive integer. As such, nodes nd0 and nd1 are coupled together by the conductive path that includes M(k+j) segment 230(1). Depending upon the value of j, there are one or more metallization layers between layer M(k) and layer M(k+j). In FIG. 1A, relative to the Y-axis, M(k+j) segment 230(1) is between (A) P+ active regions 222(1) and 222(2) and (B) N+ active regions 220(2) and 220(3).

The conductive path that couples together nodes nd0 and nd1 and that includes M(k+j) segment 230(1) represents resistor R0 of FIG. 1A. A resistance of resistor R0 is based primarily upon a resistance of M(k+j) segment 230(1). In some embodiments, the resistance of resistor R0 is adjusted (or tuned) by controlling the length of M(k+j) segment 230(1).

Relative to the X-axis: a left end of M(k+j) segment 230(1) overlaps each of P+ active region 222(1) and N+ active region 220(2); and a right end of M(k+j) segment 230(1) overlaps each of P+ active region 222(2) and N+ active region 220(3).

For simplicity of illustration, sizes S1-S3 and lengths L1-L3 are omitted from FIGS. 2B-2H.

Regarding FIG. 2B, resistor-diode ladder region 204A(2) is similar to resistor-diode ladder region 204A(1) of FIG. 2A. For brevity, the discussion will focus on differences of resistor-diode ladder region 204A(2) as compared to resistor-diode ladder 204A(1) rather than on similarities.

Differences between resistor-diode ladder region 204A(2) and resistor-diode ladder region 204A(1) include the following. In FIG. 2B. M(k) segment 226(3) replaces M(k) segment 226(2); and M(k+j) segment 230(2) replaces M(k+j) segment 230(1). M(k) segment 226(3) overlaps a left end of each of P+ active region 222(2) and N+ active region 220(3). As compared to M(k) segment 226(2) of FIG. 2A, M(k) segment 226(3) is shorter. M(k) segment 226(3) represents a version of resistor R0 that has a lower/smaller resistance than the version of resistor R0 represented by M(k) segment 226(2).

Regarding FIG. 2C, resistor-diode ladder region 204A(3) is similar to resistor-diode ladder region 204A(2) of FIG. 2B. For brevity, the discussion will focus on differences of resistor-diode ladder region 204A(3) as compared to resistor-diode ladder 204A(2) rather than on similarities.

Differences between resistor-diode ladder region 204A(3) and resistor-diode ladder region 204A(2) include the following. In FIG. 2C. M(k) segments 226(4) and 226(6) replace M(k) segment 226(1); M(k) segments 226(5) and 226(7) replace M(k) segment 226(3); and M(k+j) segments 230(3) and 226(4) replace M(k+j) segment 230(1).

M(k) segment 226(4) overlaps P+ active region 222(1) but not N+ active region 220(2). M(k) segment 226(4) overlaps N+ active region 220(2) but not P+ active region 222(3). M(k) segment 226(5) overlaps P+ active region 222(2) but not N+ active region 220(3). M(k) segment 2260(5) overlaps N+ active region 220(3) but not P+ active region 222(2).

M(k+j) segment 230(3) overlaps M(k) segments 226(4) and 226(5) but not M(k) segments 226(6) and 226(7). M(k+j) segment 230(4) overlaps M(k) segments 226(6) and 226(7) but not M(k) segments 226(4) and 226(5).

Each of M(k) segments 226(4) and 226(6) is coupled to node nd0. Each of M(k) segments 226(5) and 226(7) is coupled to node nd1. M(k+j) segments 230(3) and 230(4) correspondingly represent resistors R0_A and R0_B. Resistors R0_A and R0_B are coupled in parallel (exploded view 116 of FIG. 1A) and represent resistor R0 of FIG. 1A.

In some embodiments, resistor-diode ladder region 204A(3) of FIG. 2C facilitates routing more effectively than resistor-diode ladder region 204A(2) of FIG. 2B. In some embodiments, resistor-diode ladder region 204A(2) of FIG. 2B facilitates routing more effectively than resistor-diode ladder region 204A(3) of FIG. 2C.

In FIG. 2C: section line 3D-3D′ corresponds to cross-sectional view 338D of FIG. 3D; and section line 3E-3E′ corresponds to cross-sectional view 338E of FIG. 3E.

For simplicity of illustration, metallization segments are omitted from FIGS. 2D-2G.

Regarding FIG. 2D, resistor-diode ladder region 204D is similar to resistor-diode ladder region 204A(1) of FIG. 2A. For brevity, the discussion will focus on differences of resistor-diode ladder region 204D as compared to resistor-diode ladder 204A(1) rather than on similarities.

In FIG. 2D, resistor-diode ladder region 204E is an example of resistor-diode ladder 104B of FIG. 1B.

Differences between resistor-diode ladder region 204D and resistor-diode ladder region 204A(1) include the following. Relative to an axis of rotation parallel to the Y-axis, resistor-diode ladder region 204A(2) has been rotated 180° (degrees), and substitutions are made to the rotated version of resistor-diode ladder region 204A(2) to produce resistor-diode ladder region 204D. The substitutions include: P+ active region 222(4) (which has length L2) replaces P+ active region 222(2); P+ active region 222(5) (which has length L1) replaces P+ active region 222(1); N+ active region 220(4) (which has length L2) replaces N+ active region 220(3); and N+ active region 220(5) (which has length L1) replaces N+ active region 220(2).

Regarding FIG. 2E, resistor-diode ladder region 204E is similar to resistor-diode ladder region 204A(1) of FIG. 2A. For brevity, the discussion will focus on differences of resistor-diode ladder region 204E as compared to resistor-diode ladder 204A(1) rather than on similarities.

Differences between resistor-diode ladder region 204E and resistor-diode ladder region 204A(1) include the following. P+ active region 222(6) (which has a length L4) and P+ active region 222(5) of FIG. 2D collectively replace P+ active region 222(2); and N+ active region 220(6) (which has length L4) and N+ active region 220(5) of FIG. 2D collectively replace N+ active region 220(3).

In FIG. 2E, P+ active region 222(6) and a corresponding overlapping portion of N+ active region 220(1) correspondingly represent an anode and a cathode of a first diode D2(0) that includes a first PN junction. P+ active region 222(1) and a corresponding overlapping portion of N+ active region 220(1) correspondingly represent an anode and a cathode of a second diode D2(1) that includes a second PN junction. P+ active region 222(5) and a corresponding overlapping portion of N+ active region 220(1) correspondingly represent an anode and a cathode of a third diode D2(2) that includes a third PN junction. As a length of overlap between P+ active region 222(6) and N+ active region 220(1) is greater than a length of overlap between P+ active region 222(1) and N+ active region 220(1), diode D2(0) is larger than diode D2(1). As a length of overlap between P+ active region 222(5) and N+ active region 220(1) is about the same as a length of overlap between P+ active region 222(1) and N+active region 220(1), diode D2(2) is about the same size as diode D2(1). In some embodiments, diode D2(2) is smaller than diode D2(1). Relative to the X-axis: diode D2(0) is between diodes D2(1) and D2(2) such that a left-to-right spatial sequence is D2(1)↔D2(0)↔D2(2).

In FIG. 2E, N+ active region 220(6) and a corresponding overlapping portion of the P+ active region 222(3) correspondingly represent a cathode and an anode of a fourth diode D1(0) that includes a fourth PN junction. N+ active region 220(2) and a corresponding overlapping portion of a P+ active region 222(3) correspondingly represent a cathode and an anode of a fifth diode D1(1) that includes a fifth PN junction. N+ active region 220(5) and a corresponding overlapping portion of a P+ active region 222(3) correspondingly represent a cathode and an anode of a sixth diode D1(2) that includes a sixth PN junction. As a length of overlap between N+ active region 220(6) and P+ active region 222(3) is greater than a length of overlap between N+ active region 220(2) and P+ active region 222(3), diode D1(0) is larger than diode D1(1). As a length of overlap between N+ active region 220(5) and P+ active region 222(3) is about the same as a length of overlap between N+ active region 220(2) and P+ active region 223(3), diode D1(2) is about the same size as diode D1(1). In some embodiments, diode D1(2) is smaller than diode D1(1). Relative to the X-axis: diode D1(0) is between diodes D1(1) and D1(2) such that a left-to-right spatial sequence is D1(1)↔D1(0)↔D1(2).

In a context in which FIG. 2E is a variation of FIG. 2A, further differences (not shown) between resistor-diode ladder region 204E and resistor-diode ladder region 204A(1) include the following. A third M(k) segment overlaps a right end of each of P+ active region 222(6) and N+ active region 220(6). A fourth M(k) segment overlaps each of P+ active region 222(5) and N+ active region 220(5). A third M(k+j) segment, which is substantially coaxially aligned with M(k+1) segment 230(2), overlaps each of the third and fourth M(k) segments and represents resistor R1 of FIG. 1B.

In some embodiments, FIG. 2E is a variation of FIG. 2C. Further differences (not shown) between resistor-diode ladder region 204E and resistor-diode ladder region 204A(3) include the following. A third M(k) segment overlaps a right end of P+ active region 222(6). A fourth M(k) segment overlaps P+ active region 222(5). A fifth M(k) segment overlaps a right end of N+ active region 220(6). A sixth M(k) segment overlaps N+ active region 220(5). A third M(k+j) segment, which is substantially coaxially aligned with M(k+1) segment 230(3), overlaps each of the third and fourth M(k) segments and represents resistor R1_A. A fourth M(k+j) segment, which is substantially coaxially aligned with M(k+1) segment 230(4), overlaps each of the fifth and sixth M(k) segments and represents resistor R1_B. Resistors R1_A and R1_B are coupled in parallel (similarly to exploded view 116 of FIG. 1A) and represent resistor R1 of FIG. 1B.

Regarding FIG. 2F, resistor-diode ladder region 204F is similar to resistor-diode ladder region 204E of FIG. 2E. For brevity, the discussion will focus on differences of resistor-diode ladder region 204F as compared to resistor-diode ladder 204E rather than on similarities.

Differences between resistor-diode ladder region 204F and resistor-diode ladder region 204E include the following. Relative to the X-axis: P+ active region 222(6) is shifted leftward so that a left side boundary of P+ active region 222(6) substantially aligns with at least a left side boundary of N+ active region 220(1); N+ active region 220(6) is shifted leftward so that a left side boundary of N+ active region 220(6) substantially aligns with at least a left side boundary of P+ active region 222(3); P+ active region 222(1) is shifted rightward to be between P+ active region 222(5) to the right and now shifted P+ active region 220(6) to the left; and N+ active region 220(2) is shifted rightward to be between N+ active region 222(5) to the right and now shifted P+ active region 220(6) to the left.

In FIG. 2F, substitutions are made to the shifted version of resistor-diode ladder region 204E to produce resistor-diode ladder region 204F. The substitutions include: P+ active region 222(7) (which has length L4) replaces P+ active region 222(6); P+ active region 222(8) (which has length L1) replaces P+ active region 222(1); N+ active region 220(7) (which has length L4) replaces N+ active region 220(6); and N+ active region 220(8) (which has length L1) replaces N+ active region 220(2).

In FIG. 2F, relative to the X-axis: diode D2(1) is between diodes D2(0) and D2(2) such that a left-to-right spatial sequence is D2(0)↔D2(1)↔D2(2); and Relative to the X-axis: diode D1(1) is between diodes D1(0) and D1(2) such that a left-to-right spatial sequence is D1(0)↔D1(1)↔D1(2).

Regarding FIG. 2G, resistor-diode ladder region 204G is similar to resistor-diode ladder region 204F of FIG. 2F. For brevity, the discussion will focus on differences of resistor-diode ladder region 204G as compared to resistor-diode ladder 204F rather than on similarities.

Differences between resistor-diode ladder region 204G and resistor-diode ladder region 204F include the following. Relative to the X-axis: P+ active region 222(8) is shifted rightward so that a right side boundary of P+ active region 222(8) substantially aligns with at least a right side boundary of N+ active region 220(1); N+ active region 220(8) is shifted rightward so that a right side boundary of N+ active region 220(8) substantially aligns with at least a right side boundary of P+ active region 222(3); P+ active region 222(5) is shifted leftward to be between P+ active region 222(7) to the left and now shifted P+ active region 220(8) to the right; and N+ active region 220(5) is shifted leftward to be between N+ active region 222(7) to the left and now shifted P+ active region 220(8) to the right.

In FIG. 2G, substitutions are made to the shifted version of resistor-diode ladder region 204F to produce resistor-diode ladder region 204G. The substitutions include: P+ active region 222(9) (which has length L1) replaces P+ active region 222(5); P+ active region 222(10) (which has length L1) replaces P+ active region 222(8); N+ active region 220(9) (which has length L1) replaces N+ active region 220(5); and N+ active region 220(10) (which has length L1) replaces N+ active region 220(8).

Relative to the X-axis: diode D2(2) is between diodes D2(0) and D2(1) such that a left-to-right spatial sequence is D2(0)↔D2(2)↔D2(1); and In FIG. 2G, relative to the X-axis: diode D1(2) is between diodes D1(0) and D1(1) such that a left-to-right spatial sequence is D1(0)↔D1(2)↔D1(1).

Regarding FIG. 2H, resistor-diode ladder region 204H is similar to resistor-diode ladder region 204A(1) of FIG. 2A. For brevity, the discussion will focus on differences of resistor-diode ladder region 204H as compared to resistor-diode ladder 204A(1) rather than on similarities.

Differences between resistor-diode ladder region 204GH and resistor-diode ladder region 204A(1) include the following. In FIG. 2H, M(k) segment 226(8) replaces M(k) segment 226(2). M(k) segment 226(3) overlaps M(k+j) segment 230(1) and a right end of of P+ active region 222(2) but does not overlap a right end of N+ active region 220(3). Resistor-diode ladder region 204H is an example of a version of resistor-diode ladder 104A of FIG. 1A in which diode D1(1) is omitted.

FIGS. 3A-3B are corresponding layout diagrams, in accordance with some embodiments.

FIG. 3A shows a metal layer M(k+p) 332 in an ESDP circuit, where p is a positive integer. Examples of the ESDP circuit include ESDP circuits disclosed herein, or the like.

In some embodiments, p=5 such that metal layer 332 is metal layer M(k+5) (FIGS. 3B-3C). Metal layer 332 is arranged into a section overlying a resistor-diode ladder region and a power clamp region. Examples of the the resistor-diode ladder region of FIG. 3A include the resistor-diode ladder regions disclosed herein, or the like. Examples of the power clamp region include power clamp regions in semiconductor devices that include ESDP circuits such as the ESDP circuits disclosed herein, or the like.

FIG. 3B is a layout diagram 334 of multiple stacked metal layers in an ESDP circuit.

Layout diagram 334 includes metal layers M(k), M(k+1), M(k+2), M(k+3), M(k+4), and M(k+5), where M(k+5) corresponds to the metal layer of FIG. 3A. Similarly to FIG. 3A, FIG. 3B is arranged into a section overlying a resistor-diode ladder region and a power clamp region.

FIG. 3C is a cross-sectional diagram 336 of a portion of an ESDP circuit of a semiconductor device, in accordance with some embodiments.

FIG. 3C corresponds to section line IIIC-IIIC′ of FIG. 3B. In FIG. 3C, as the layers transition from the segment in metal layer M(k+5) at the top to the segment in metal layer M(k) at the bottom, the metal layers extend progressively farther to the left in a stair configuration (or stepped configuration). In some embodiments, such a stair configuration is used to reduce fringe capacitance between various segments in metal layers M(k) to M(k+5).

FIGS. 3D-3E are corresponding cross-sectional views 338D and 338E of a resistor-diode ladder region, in accordance with some embodiments.

The resistor-diode ladder region of FIGS. 3D-3E is an example of a resistor-diode ladder region based on resistor-diode ladder region 204A(3) of FIG. 2C.

FIGS. 3D-3E FIGS. 3D-3E follow a similar numbering scheme to that of FIG. 2C however FIGS. 3D-3E use 3-series numbering whereas FIG. 2C uses 2-series number. In general, number similarities indicate correspondence. For example, N-well 324 in FIGS. 3D-3E correspond to N-well 224 in FIG. 2A.

In FIG. 3D, each of cross-sections 338D-338E includes: P-type substrate 340; an N-well 324; a P+ active region 322(2); instances of a metal-to-source/drain (MD) contact structure 342; M(i) segment 326(5); in an interconnection layer VIA(i) (not called out), instances of via contact structure V(i) 344; and M(i+j) segment 330(3). In FIG. 3D, cross-section 338D additionally includes: an N+ active region 320(2); and M(i) segment 326(4). In FIG. 3E, cross-section 338E additionally includes: an N+ active region 320(3); M(i) segment 326(7); and M(i+j) segment 330(4).

In FIGS. 3D and/or 3B: N-well 324 is in P-type substrate 340; N+ active region 320(2) and P+ active region 322(2) are in N-well. 324; instances of a MD contact structure 342 are between a portion of an active region and a corresponding portion of an M(i) segment; instances of V(i) 344 are between a portion of an M(i) segment and a corresponding portion of an M(i+j) segment.

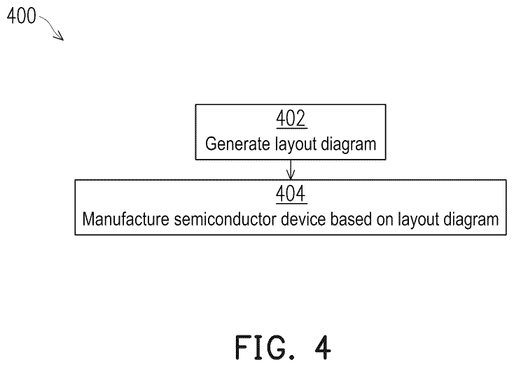

FIG. 4 is a flowchart 400 of a method of manufacturing a semiconductor device, in accordance with some embodiments.

The method of flowchart (flow diagram) 400 is implementable, for example, using EDA system 800 (FIG. 8, discussed below) and an IC manufacturing system 900 (FIG. 9, discussed below), in accordance with some embodiments. Examples of a semiconductor device which can be manufactured according to the method of flowchart 400 include semiconductor devices disclosed herein, semiconductor devices based on the layout diagrams disclosed herein, or the like.

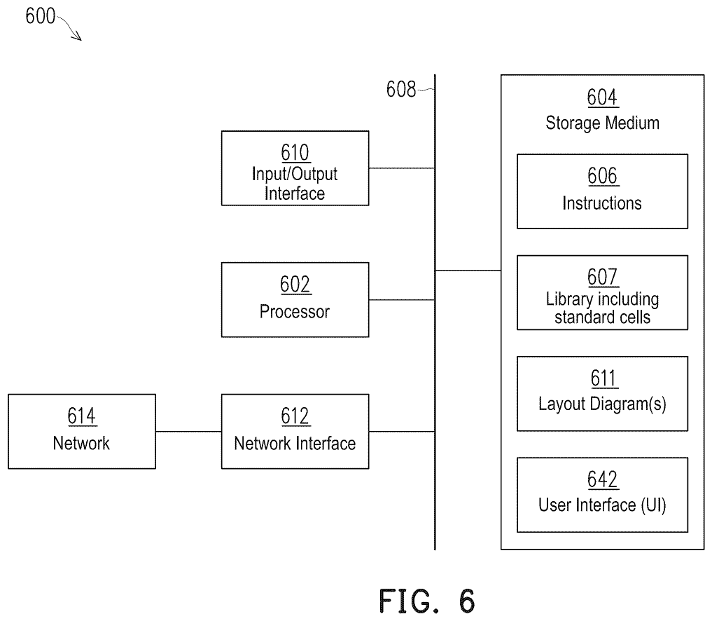

In FIG. 4, the method of flowchart 400 includes blocks 402-704. At block 402, a layout diagram is generated which, among other things, includes one or more of layout diagrams disclosed herein, or the like. Block 402 is implementable, for example, using EDA system 600 (FIG. 6, discussed below), in accordance with some embodiments.

In some embodiments, at block 402, a layout diagram is generated. Examples of the layout diagram include the layout diagrams disclosed herein, layout diagrams according to the electrostatic discharge protection (ESDP) circuits disclosed herein, layout diagrams according to the resistor-diode ladders disclosed herein, or the like. From block 402, flow proceeds to block 404.

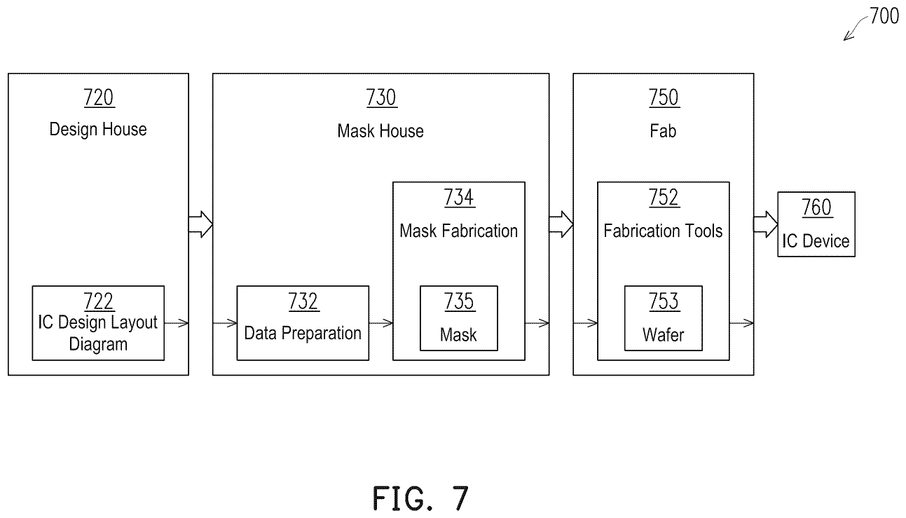

At block 404, based on the layout diagram of block 402, at least one of (A) one or more photolithographic exposures are made or (b) one or more semiconductor masks are fabricated or (C) one or more components in a layer of a semiconductor device are fabricated. See discussion below of IC manufacturing system 700 in FIG. 7 below.

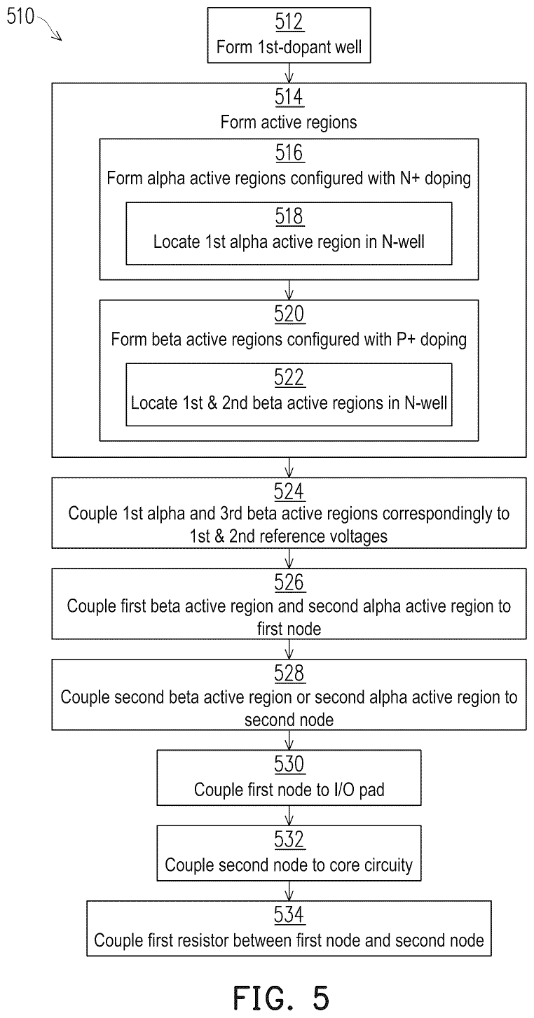

FIG. 5 is a flowchart 510 of a method of fabricating a resistor-diode ladder region of a semiconductor device, in accordance with some embodiments.

Flowchart 510 is an example of block 404 of FIG. 4. Flowchart 510 includes blocks 512-534. Examples provided in the context of the discussion of blocks 512-740 assume first, second and third orthogonal directions that are, e.g., correspondingly parallel to the X-axis, Y-axis and Z-axis. The method of flowchart 510 is implementable, for example, using IC manufacturing system 700 (FIG. 7, discussed below), in accordance with some embodiments. Examples of a semiconductor device which can be manufactured according to the method of flowchart 510 include semiconductor devices disclosed herein, semiconductor devices based on the layout diagrams disclosed herein, or the like.

In FIG. 5, at block 512, a first-dopant-type well is formed. An example of first dopant type is an N-type dopant. An example of the first-dopant-type well is N-well 224 of FIG. 2A, or the like. From block 512, flow proceeds to block 514.

At block 514, active regions are formed. Block 514 includes blocks 516-522.

At block 516, alpha active regions are formed which are configured with the first dopant type to function as either cathodes or anodes of corresponding diodes. Examples of the alpha active regions include N+ active regions 220(1)-220(3) of FIG. 2A that function as corresponding cathodes, or the like. Block 516 includes block 518.

At block 518, a first alpha active region is located/formed in the first-dopant-type well. An example of the first alpha active region in the first-dopant-type well is N+ active region 220(1) in N-well 224. In some embodiments, block 518 includes substantially coaxially aligning a second alpha active region and a third alpha active region. An example of substantially coaxially aligned second and third alpha active regions is substantially coaxially aligned N+ active regions 220(2) and 220(3) of FIG. 2A, or the like. From block 518, flow exits block 516 and proceeds to block 520.

At block 520, beta active regions are formed which are configured with a second dopant type different than the first dopant type to function complementarily as either anodes or cathodes of corresponding diodes. An example of the second dopant type is a P-type dopant. Examples of the beta active regions include P+ active regions 222(1)-222(3) of FIG. 2A that function as corresponding anodes, or the like. Block 520 includes block 522.

At block 522, first and second beta active regions are located/formed in the first-dopant-type well. Examples of the first and second beta active regions in the first-dopant-type well correspondingly are P+ active regions 222(1) and 222(2) in N-well 224. In some embodiments, block 522 includes substantially coaxially aligning the second and third beta active regions. An example of substantially coaxially aligned second and third beta active regions is substantially coaxially aligned P+ active regions 221(1) and 221(2) of FIG. 2A, or the like. From block 522, flow exits block 520 and proceeds to block 524.

As a result of block 514, first, second, third and fourth diodes are produced. Examples of the first to fourth diodes correspondingly include diodes D2(1), D2(0), D1(1) and D1(0) of FIG. 2A, or the like.

At block 524, the first alpha active region and the third active regions are correspondingly coupled to different first and second reference voltages. Examples of the first and second reference voltages correspondingly are VDD and VSS, or the like. An example of the first alpha active region being coupled to the first reference voltage is N+ active region 220(1) being coupled to VDD in FIG. 2A, or the like. An example of the third beta active region being coupled to the second reference voltage is P+ active region 222(3) being coupled to VSS in FIG. 2A, or the like. From block 524, flow proceeds to block 526.

At block 526, the first beta active region and a second alpha active region are coupled to a first node. An example of the first node is node nd0 of FIG. 2A to which P+ active region 222(1) and N+ active region 220(2) are coupled, or the like. From block 526, flow proceeds to block 528.

At block 528, the second beta active region or a third alpha active region are coupled to a second node. An example of the second node is node nd1 of FIG. 2A to which P+ active region 222(2) and N+ active region 220(3) are coupled, or the like. An example of the second beta active region but not the third alpha active region being coupled to the second node is in FIG. 2H where P+ active region 222(2) is coupled to node nd1 but N+ active region 220(3) is not coupled to node nd1, or the like. From block 528, flow proceeds to block 530.

At block 530, the first node is coupled to an I/O pad. An example of the first node being coupled to an I/O pad is node nd0 being coupled to I/O pad 108 in FIG. 2A, or the like. From block 530, flow proceeds to block 532.

At block 532, the second node is coupled to core circuitry. An example of the second node being coupled to core circuitry is node nd1 being coupled to core circuitry 110 in FIG. 2A, or the like. From block 523, flow proceeds to block 534.

At block 534, a first resistor is coupled between the first node and the second node. An example of the resistor is resistor RO of FIG. 1A which is represented by M(k) segment 230(1) in FIG. 2A, or the like.

In some embodiments, block 534 includes forming metallization layers stacked over the first and second active regions including:

forming a kth metallization layer over the first and second active regions including one or more M(k) segments (e.g., 226(x) in FIGS. 2A-2C, 2H, or the like) extending parallel to the Y-axis), where k is a non-negative integer; and

forming a (k+j)th metallization layer over the kth metallization layer, the (k+j) th metallization layer including one or more M(k+1) segments (230(x) in FIGS. 2A-2C, 2H, or the like) extending in parallel to the X-axis, where j is a positive integer; wherein the the first resistor (e.g., R0) is represented substantially by the one or more M(k+1) segments (e.g., 230(3) and 230(4) in FIG. 2C, or the like).

In some embodiments, one or more of blocks 526-534 is/are iterated to add more diodes and corresponding resistors, e.g., as in FIGS. 1B-1C. 2E-2G, or the like.

FIG. 6 is a block diagram of an electronic design automation (EDA) system 600 in accordance with some embodiments.

In some embodiments, EDA system 600 includes an automatic placement and routing (APR) system. In some embodiments, EDA system 600 is a general purpose computing device including a hardware processor 602 and a non-transitory, computer-readable storage medium 604. Storage medium 604, amongst other things, is encoded with, i.c., stores, computer program code 606, i.e., a set of executable instructions. Execution of instructions 606 by hardware processor 602 represents (at least in part) an EDA tool which implements a portion or all of, e.g., the method of FIG. 4 (block 402), methods of generating layout diagrams such as the layout diagrams disclosed herein, layout diagrams according to the electrostatic discharge protection (ESDP) circuits disclosed herein, layout diagrams according to the resistor-diode ladders disclosed herein, or the like, in accordance with one or more embodiments (hereinafter, the noted processes and/or methods). Storage medium 604, amongst other things, stores layout diagrams 611 such as the layout diagrams disclosed herein, other the like.

Processor 602 is electrically coupled to computer-readable storage medium 604 via a bus 608. Processor 602 is further electrically coupled to an I/O interface 610 by a bus 608. A network interface 612 is further electrically connected to processor 602 via bus 608. Network interface 612 is connected to a network 614, so that processor 602 and computer-readable storage medium 604 are capable of connecting to external elements via network 614. Processor 602 is configured to execute computer program code 606 encoded in computer-readable storage medium 604 in order to cause system 600 to be usable for performing a portion or all of the noted processes and/or methods. In one or more embodiments, processor 602 is a central processing unit (CPU), a multi-processor, a distributed processing system, an application specific integrated circuit (ASIC), and/or a suitable processing unit.

In one or more embodiments, computer-readable storage medium 604 is an electronic, magnetic, optical, electromagnetic, infrared, and/or a semiconductor system (or apparatus or device). For example, computer-readable storage medium 604 includes a semiconductor or solid-state memory, a magnetic tape, a removable computer diskette, a random access memory (RAM), a read-only memory (ROM), a rigid magnetic disk, and/or an optical disk. In one or more embodiments using optical disks. computer-readable storage medium 604 includes a compact disk-read only memory (CD-ROM), a compact disk-read/write (CD-R/W), and/or a digital video disc (DVD).

In one or more embodiments, storage medium 604 stores computer program code 606 configured to cause system 600 (where such execution represents (at least in part) the EDA tool) to be usable for performing a portion or all of the noted processes and/or methods. In one or more embodiments. storage medium 604 further stores information which facilitates performing a portion or all of the noted processes and/or methods. In one or more embodiments, storage medium 604 stores library 607 of standard cells including such standard cells as disclosed herein. In some embodiments, storage medium 604 stores one or more layout diagrams 611.

EDA system 600 includes I/O interface 610. I/O interface 610 is coupled to external circuitry. In one or more embodiments, I/O interface 610 includes a keyboard, keypad, mouse, trackball, trackpad, touchscreen, and/or cursor direction keys for communicating information and commands to processor 602.

EDA system 600 further includes network interface 612 coupled to processor 602. Network interface 612 allows system 600 to communicate with network 614, to which one or more other computer systems are connected. Network interface 612 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 600.

System 600 is configured to receive information through I/O interface 610. The information received through I/O interface 610 includes one or more of instructions, data, design rules, libraries of standard cells, and/or other parameters for processing by processor 602. The information is transferred to processor 602 via bus 608. EDA system 600 is configured to receive information related to a user interface (UI) through I/O interface 610. The information is stored in computer-readable medium 604 as UI 642.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 600. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 7 is a block diagram of an integrated circuit (IC) manufacturing system 700, and an IC manufacturing flow associated therewith, in accordance with some embodiments.

Based on the layout diagram generated by block 402 of FIG. 4, the IC manufacturing system 700 implements block 404 of FIG. 4 wherein at least one of (A) one or more semiconductor masks or (B) at least one component in a layer of an inchoate semiconductor integrated circuit is fabricated using manufacturing system 700.

In FIG. 7, IC manufacturing system 700 includes entities, such as a design house 720, a mask house 730, and an IC manufacturer/fabricator (“fab”) 750, that interact with one another in the design, development, and manufacturing cycles and/or services related to manufacturing an IC device 760. The entities in system 700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 720, mask house 730, and IC fab 750 is owned by a single larger company. In some embodiments, two or more of design house 720, mask house 730, and IC fab 750 coexist in a common facility and use common resources.

Design house (or design team) 720 generates an IC design layout 722. IC design layout 722 includes various geometrical patterns designed for an IC device 760. The geometrical patterns correspond to patterns of metal, oxide, or semiconductor layers that make up the various components of IC device 760 to be fabricated. The various layers combine to form various IC features. For example, a portion of IC design layout 722 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 720 implements a proper design procedure to form IC design layout 722. The design procedure includes one or more of logic design, physical design or place and route. IC design layout 722 is presented in one or more data files having information of the geometrical patterns. For example, IC design layout 722 is expressed in a GDSII file format or DFII file format.

Mask house 730 includes data preparation 732 and mask fabrication 734. Mask house 730 uses IC design layout 722 to manufacture one or more masks 735 to be used for fabricating the various layers of IC device 760 according to IC design layout 722. Mask house 730 performs mask data preparation 732, where IC design layout 722 is translated into a representative data file (“RDF”). Mask data preparation 732 supplies the RDF to mask fabrication 734. Mask fabrication 734 includes a mask writer. A mask writer converts the RDF to an image on a substrate, such as a mask (reticle) or a semiconductor wafer. The design layout is manipulated by mask data preparation 732 to comply with particular characteristics of the mask writer and/or requirements of IC fab 750. In FIG. 7, mask data preparation 732, mask fabrication 734, and mask 735 are illustrated as separate elements. In some embodiments, mask data preparation 732 and mask fabrication 734 are collectively referred to as mask data preparation.

In some embodiments. mask data preparation 732 includes optical proximity correction (OPC) which uses lithography enhancement techniques to compensate for image errors, such as those that can arise from diffraction, interference, other process effects and the like. OPC adjusts IC design layout 722. In some embodiments, mask data preparation 732 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 732 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 734, which may und0 part of the modifications performed by OPC in order to meet mask creation rules.

In some embodiments, mask data preparation 732 includes lithography process checking (LPC) that simulates processing that will be implemented by IC fab 750 to fabricate IC device 760. LPC simulates this processing based on IC design layout 722 to fabricate a simulated manufactured device, such as IC device 760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are be repeated to further refine IC design layout 722.

The above description of mask data preparation 732 has been simplified for the purposes of clarity. In some embodiments, mask data preparation 732 includes additional features such as a logic operation (LOP) to modify the IC design layout according to manufacturing rules. Additionally, the processes applied to IC design layout 722 during data preparation 732 may be executed in a variety of different orders.

After mask data preparation 732 and during mask fabrication 734, a mask 735 or a group of masks 735 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 734 is used in a variety of processes. For example, such a mask(s) is used in an ion implantation process to form various doped regions in the semiconductor wafer, in an etching process to form various etching regions in the semiconductor wafer, and/or in other suitable processes.

IC fab 750 is an IC fabrication business that includes one or more manufacturing facilities for the fabrication of a variety of different IC products. In some embodiments, IC fab 750 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 750 uses mask (or masks) 735 fabricated by mask house 730 to fabricate IC device 760 using fabrication tools 752. Thus, IC fab 750 at least indirectly uses IC design layout 722 to fabricate IC device 760. In some embodiments, a semiconductor wafer 753 is fabricated by IC fab 750 using mask (or masks) 735 to form IC device 760. Semiconductor wafer 753 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, resistor-diode ladder includes: a first diode coupled between a first node and a first power rail having a first reference voltage; a first resistor coupled between the first node and a second node; and a second diode coupled between the second node and the first power rail; the first node being coupled to an input/output (I/O) pad of a semiconductor device; and the resistor-diode ladder being coupled between the I/O pad and core circuitry of the semiconductor device.

In some embodiments, the resistor-diode ladder further includes: a third diode coupled between the first node and a second power rail having a second reference voltage different than the first reference voltage; a fourth diode coupled between the second node and the second power rail.

In some embodiments, the resistor-diode ladder further includes: a second resistor coupled between the second node and a third node; a fifth diode coupled between the third node and the first power rail; and a sixth diode coupled between the third node and the second power rail.

In some embodiments, the first diode is larger than the second diode; the third diode is larger than the fourth diode; the first and second diodes have a size ratio SR; and the third and fourth diodes have the size ratio SR.

In some embodiments, the size ratio SR is in a range (≈9.0)≤SR≤(≈1.0).

In some embodiments, the size ratio SR is in a range (≈6.0)≤SR≤(≈4.0).

In some embodiments, the resistor-diode ladder of claim 1, further includes: a third diode coupled between the first node and a second power rail having a second reference voltage different than the first reference voltage; and wherein a first number representing a total of the diodes coupled to the first power rail is different than a second number representing a total of the one or more diodes coupled to the second power rail.

In some embodiments, an electrostatic discharge (ESD) protection cell region (of a semiconductor device) includes: a resistor-diode ladder and a power clamp circuit coupled in parallel between a first power rail having a first reference voltage and a second power rail having a second reference voltage different than the first reference voltage; and the resistor-diode ladder also being coupled between an input/output (I/O) pad of the semiconductor device and core circuitry of the semiconductor device.

In some embodiments, the resistor-diode ladder further includes: a first diode coupled between a first node and the first power rail; a first resistor coupled between the first node and a second node; and a second diode coupled between the second node and the first power rail; the first node being coupled to the I/O pad; and the resistor-diode ladder being coupled between the I/O pad and the core circuitry.

In some embodiments, the resistor-diode ladder further includes: a third diode coupled between the first node and the second power rail; and a fourth diode coupled between the second node and the second power rail.

In some embodiments, the resistor-diode ladder further includes: a second resistor coupled between the second node and a third node; a fifth diode coupled between the third node and the first power rail; and a sixth diode coupled between the third node and the second power rail.

In some embodiments, the first diode is larger than the second diode; the third diode is larger than the fourth diode; the first and second diodes have a size ratio SR; and the third and fourth diodes have the size ratio SR.

In some embodiments, the size ratio SR is in a range (≈9.0)≤SR≤(≈1.0).

In some embodiments, the size ratio SR is in a range (≈6.0)≤SR≤(≈4.0).

In some embodiments, a resistor-diode ladder region (of a semiconductor device) includes: alpha active regions extending in a first direction and being configured with a first dopant-type to function as either cathodes or anodes of corresponding diodes; beta active regions extending in the first direction and being configured with a second dopant type different than the first dopant type to function complementarily as either anodes or cathodes of corresponding diodes; and a well region configured with the first dopant-type; a first alpha active region and first and second beta active regions being in the well region; the first beta active region and a corresponding overlapping portion of the first alpha active region representing corresponding portions of a first diode; the second beta active region and a corresponding overlapping portion of the first alpha active region representing corresponding portions of a second diode; a second alpha active region and a corresponding overlapping portion of a third beta active region representing corresponding portions of a third diode; a third alpha active region and a corresponding overlapping portion of the third beta active region representing corresponding portions of a fourth diode; the first alpha active region and the third beta active region being coupled correspondingly to different first and second reference voltages; the first beta active region and the second alpha active region being coupled to a first node; the second beta active region or the third alpha active region being coupled to a second node; and a first resistor coupling the first node to the second node.

In some embodiments, the first and second alpha active regions are substantially coaxially aligned; and the first and second beta active regions correspondingly are substantially coaxially aligned.

In some embodiments, relative to a second direction perpendicular to the first direction, the first and second beta active regions are between (A) the first alpha active region and (B) the second and third alpha active regions, and the second and third alpha active regions are between (C) the first and second beta active regions and (D) the third beta alpha active region.

In some embodiments, the first node is coupled to an input/output (I/O) pad of the semiconductor device.

In some embodiments, the resistor-diode ladder is coupled between the I/O pad and core circuitry of the semiconductor device.

In some embodiments, relative to the second direction, each of the first alpha active region and the third beta active region substantially has a first height, and each of the second and third alpha active regions and the first and second beta active regions substantially has a second height.

In some embodiments, the first height is approximately the same as the second height.

In some embodiments, relative to the first direction, each of the first alpha active region and the third beta active region substantially has a first length, each of the third alpha active region and the second beta active region substantially has a second length, and each of the second alpha active region and the first beta active region has a third length.

In some embodiments, the third length is smaller than the second length; and the second length is smaller than the first length.

In some embodiments, the third length is substantially same as the second length; and each of the second length and the third length is smaller than the first length.

In some embodiments, the resistor-diode ladder region further includes metallization layers stacked over the alpha and beta active regions including: an i^{th} metallization layer over the first and second active regions including one or more M(i) segments extending in the second direction, where i is a non-negative integer; and a (i+j)^{th} metallization layer over the i^{th} metallization layer, the (i+j)^{th} metallization layer including one or more M(i+1) segments extending in the first direction, where j is a positive integer; and the first resistor is represented substantially by the one or more M(i+1) segments.

In some embodiments, a resistance of the first resistor is based primarily upon a resistance of the one or more M(i+1) segments; and the resistance of the one or more M(i+1) segments is based substantially on corresponding lengths of the one or more M(i+1) segments relative to the first direction.

In some embodiments, relative to the second direction, the one or more M(i+1) segments are between (A) the first and second alpha active regions and (B) the first and second beta active regions.

In some embodiments, relative to the first direction: first and second ends of the third alpha active region are correspondingly proximal and distal to the second alpha active region; first and second ends of the second beta active region are correspondingly proximal and distal to the first beta active region; a first end of at least one of the one or more M(i+1) segments overlaps the first beta active region and the second alpha active region; and a second of at least one of the one or more M(i+1) segments overlaps at least the first end correspondingly of the second beta active region and the third alpha active region.

In some embodiments, the resistor-diode ladder region further includes: relative to the first direction, the second of the at least one of the one or more M(i+1) segments overlaps the second ends correspondingly of the second beta active region and the third alpha active region.

In some embodiments, the resistor-diode ladder region further includes: the first resistor is represented by second and third resistors coupled in parallel between the first node to the second node.

In some embodiments, relative to the first direction: first and second ends of the third alpha active region are correspondingly proximal and distal to the second alpha active region; first and second ends of the second beta active region are correspondingly proximal and distal to the first alpha active region; a first end of at least a first one of the one or more M(i+1) segments overlaps the first beta active region; and a second of at least the first one of the one or more M(i+1) segments overlaps at least the first end of the second beta active region; a first end of at least a second one of the one or more M(i+1) segments overlaps the second alpha active region; and a second of at least the second one of the one or more M(i+1) segments overlaps at least the first end of the third alpha active region.

In some embodiments, the second beta active region and the third alpha active region are coupled to the second node.

In some embodiments, relative to the second direction, each of the first and second beta active regions and the second and third alpha active region has substantially a first height; relative to the first direction, each of the first beta active region and the second alpha active region has substantially a first length, and each of the second beta active region and the third alpha active region has substantially a second length; the first diode is larger than the second diode; and the third diode is larger than the fourth diode.

In some embodiments, the resistor-diode ladder region further includes: a fourth alpha active region substantially coaxially aligned with the second and third alpha active regions; and a fourth beta active region substantially coaxially aligned with the first and second beta active regions; and wherein: the fourth beta active region and a corresponding overlapping portion of the first alpha active region represents corresponding portions of a fifth diode; the fourth alpha active region and a corresponding overlapping portion of a third beta active region represents corresponding portions of a sixth diode; relative to the second direction, each of the fourth beta active region and the fourth alpha active region has substantially the first height; relative to the first direction, each of the fourth beta active region and the fourth alpha active region has substantially the first length or shorter, the fifth diode is approximately equal to or smaller than the second diode, and the sixth diode is approximately equal to or smaller than the fourth diode.

In some embodiments, relative to the first direction: the second beta active region is between the first and fourth beta active regions; and the third alpha active region is between the second and fourth alpha active regions.

In some embodiments, relative to the first direction: the first beta active region is between the second and fourth beta active regions; and the second alpha active region is between the second and fourth alpha active regions.

In some embodiments, relative to the first direction: the fourth beta active region is between the second and first beta active regions; and the fourth alpha active region is between the second and second alpha active regions.

In some embodiments, a method (of forming a resistor-diode ladder region of a semiconductor device) includes: forming a well region configured with a first dopant-type; forming active regions extending in a first direction including forming alpha active regions configured with the first dopant-type to function as either cathodes or anodes of corresponding diodes, the forming alpha active regions including locating a first alpha active region in the well region; forming beta active regions configured with a second dopant type different than the first dopant type to function complementarily as either anodes or cathodes of corresponding diodes, the forming beta active regions including locating a first and second beta active regions in the well region; the first beta active region and a corresponding overlapping portion of the first alpha active region representing corresponding portions of a first diode; the second beta active region and a corresponding overlapping portion of the first alpha active region representing corresponding portions of a second diode; a second alpha active region and a corresponding overlapping portion of a third beta active region representing corresponding portions of a third diode; a third alpha active region and a corresponding overlapping portion of the third beta active region representing corresponding portions of a fourth diode; coupling the first alpha active region and the third beta active region correspondingly to different first and second reference voltages; coupling the first beta active region and the second alpha active region to a first node; coupling the second beta active region or the third alpha active region to a second node; and coupling a first resistor between the first node and the second node.

In some embodiments, the forming alpha active regions further includes substantially coaxially aligning the first and second alpha active regions; and the forming beta active regions further includes substantially coaxially aligning the first and second beta active regions.

In some embodiments, the method further includes: coupling the first node to an input/output (I/O) pad of the semiconductor device.

In some embodiments, the method further includes: coupling the resistor-diode ladder between the I/O pad and core circuitry of the semiconductor device.

In some embodiments, the method further includes forming metallization layers stacked over the first and second active regions including: forming a kth metallization layer over the first and second active regions including one or more M(k) segments extending in the second direction, where k is a non-negative integer; and forming a (k+j) th metallization layer over the kth metallization layer, the (k+j)th metallization layer including one or more M(k+1) segments extending in the first direction, where j is a positive integer; and wherein the first resistor is represented substantially by the one or more M(k+1) segments.

In some embodiments, relative to the second direction: the forming alpha active regions further includes configuring each of the first and second beta active regions to have substantially a first height; and the forming beta active regions further includes configuring each of second and third alpha active region to have substantially the first height; relative to the first direction: the forming alpha active regions further includes configuring the second alpha active region to have substantially a first length, and configuring the third alpha active region to have substantially a second length; and the forming beta active regions further includes configuring the first beta active region to have substantially the first length, and configuring the second beta active region has to have substantially the second length; the first diode is larger than the second diode; and the third diode is larger than the fourth diode.

In some embodiments, the method further includes: locating each of a fourth alpha active region and a fourth beta active region in the well region; substantially coaxially aligning the second, third and fourth alpha active regions; substantially coaxially aligning the first, second fourth and beta active regions; and the fourth beta active region and a corresponding overlapping portion of the first alpha active region representing corresponding portions of a fifth diode; the fourth alpha active region and a corresponding overlapping portion of a third beta active region representing corresponding portions of a sixth diode; relative to the second direction: the forming alpha active regions further includes configuring the fourth alpha active region to have substantially the first height; and the forming beta active regions further includes configuring the fourth beta active region and second to have substantially the first height; and relative to the first direction: the forming alpha active regions further includes configuring the fourth alpha active region to have substantially the first length or shorter; and the forming beta active regions further includes configuring the fourth beta active region to have substantially the first length or shorter; and wherein: the fifth diode is approximately equal to or smaller than the second diode; and the sixth diode is approximately equal to or smaller than the fourth diode.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. An electrostatic discharge (ESD) protection cell region of a semiconductor device, the ESD protection cell region comprising:
a resistor-diode ladder and a power clamp circuit coupled in parallel between a first power rail having a first reference voltage and a second power rail having a second reference voltage different than the first reference voltage; and
the resistor-diode ladder also being coupled between an input/output (I/O) pad of the semiconductor device and core circuitry of the semiconductor device.

2. The ESD protection cell region of claim 1, wherein the resistor-diode ladder includes:
a first diode coupled between a first node and the first power rail;
a first resistor coupled between the first node and a second node; and
a second diode coupled between the second node and the first power rail;
the first node being coupled to the I/O pad; and
the resistor-diode ladder being coupled between the I/O pad and the core circuitry.

3. The ESD protection cell region of claim 2, wherein the resistor-diode ladder includes:
a third diode coupled between the first node and the second power rail;
a fourth diode coupled between the second node and the second power rail.

4. The ESD protection cell region of claim 3, wherein the resistor-diode ladder includes:
a second resistor coupled between the second node and a third node;
a fifth diode coupled between the third node and the first power rail; and
a sixth diode coupled between the third node and the second power rail.

5. The ESD protection cell region of claim 3, wherein:
the first diode is larger than the second diode;
the third diode is larger than the fourth diode;
the first and second diodes have a size ratio SR; and
the third and fourth diodes have the size ratio SR.

6. The ESD protection cell region of claim 5, wherein:
the size ratio SR is in a range (≈9.0)≤SR≤(≈1.0).

7. The ESD protection cell region of claim 6, wherein:
the size ratio SR is in a range (≈6.0)≤SR≤(≈4.0).

8. A method of forming a resistor-diode ladder region of a semiconductor device, the method comprising:
forming a well region configured with a first dopant-type;
forming active regions extending in a first direction including:
forming alpha active regions configured with the first dopant-type to function as either cathodes or anodes of corresponding diodes, the forming alpha active regions including:
locating a first alpha active region in the well region;
forming beta active regions configured with a second dopant type different than the first dopant type to function complementarily as either anodes or cathodes of corresponding diodes, the forming beta active regions including:
locating a first and second beta active regions in the well region;
the first beta active region and a corresponding overlapping portion of the first alpha active region representing corresponding portions of a first diode;
the second beta active region and a corresponding overlapping portion of the first alpha active region representing corresponding portions of a second diode;
a second alpha active region and a corresponding overlapping portion of a third beta active region representing corresponding portions of a third diode;
a third alpha active region and a corresponding overlapping portion of the third beta active region representing corresponding portions of a fourth diode;
coupling the first alpha active region and the third beta active region correspondingly to different first and second reference voltages;
coupling the first beta active region and the second alpha active region to a first node;
coupling the second beta active region or the third alpha active region to a second node; and
coupling a first resistor between the first node and the second node.

9. The method of claim 8, wherein:
the forming alpha active regions further includes:
substantially coaxially aligning the first and second alpha active regions; and
the forming beta active regions further includes:
substantially coaxially aligning the first and second beta active regions.

10. The method of claim 8, further comprising:
coupling the first node to an input/output (I/O) pad of the semiconductor device.

11. A resistor-diode ladder region of a semiconductor device comprising:
alpha active regions extending in a first direction and being configured with a first dopant-type to function as either cathodes or anodes of corresponding diodes; and
beta active regions extending in the first direction and being configured with a second dopant type different than the first dopant type to function complementarily as either anodes or cathodes of corresponding diodes; and
a well region configured with the first dopant-type;
a first alpha active region and first and second beta active regions being in the well region;
the first beta active region and a corresponding overlapping portion of the first alpha active region representing corresponding portions of a first diode;
the second beta active region and a corresponding overlapping portion of the first alpha active region representing corresponding portions of a second diode;
a second alpha active region and a corresponding overlapping portion of a third beta active region representing corresponding portions of a third diode;
a third alpha active region and a corresponding overlapping portion of the third beta active region representing corresponding portions of a fourth diode;
the first alpha active region and the third beta active region being coupled correspondingly to different first and second reference voltages;
the first beta active region and the second alpha active region being coupled to a first node;
the second beta active region or the third alpha active region being coupled to a second node; and
a first resistor coupling the first node to the second node.

12. The resistor-diode ladder region of claim 11, wherein:
the first and second alpha active regions are substantially coaxially aligned; and
the first and second beta active regions correspondingly are substantially coaxially aligned.

13. The resistor-diode ladder region of claim 11, wherein:
the first node is coupled to an input/output (I/O) pad of the semiconductor device.

14. The resistor-diode ladder region of claim 11, wherein:
the resistor-diode ladder is coupled between the I/O pad and core circuitry of the semiconductor device.

15. The resistor-diode ladder region of claim 11, further comprising:
metallization layers stacked over the alpha and beta active regions including:
an i^{th} metallization layer over the first and second active regions including one or more M(i) segments extending in the second direction, where i is a non-negative integer; and
a (i+j)^{th} metallization layer over the i^{th} metallization layer, the (i+j) th metallization layer including one or more M(i+1) segments extending in the first direction, where j is a positive integer; and
the first resistor is represented substantially by the one or more M(i+1) segments.

16. The resistor-diode ladder region of claim 15, wherein:
a resistance of the first resistor is based primarily upon a resistance of the one or more M(i+1) segments; and
the resistance of the one or more M(i+1) segments is based substantially on corresponding lengths of the one or more M(i+1) segments relative to the first direction.

17. The resistor-diode ladder region of claim 15, wherein:
relative to the second direction,
the one or more M(i+1) segments are between (A) the first and second alpha active regions and (B) the first and second beta active regions.

18. The resistor-diode ladder region of claim 15, wherein:
relative to the first direction:
first and second ends of the third alpha active region are correspondingly proximal and distal to the second alpha active region;
first and second ends of the second beta active region are correspondingly proximal and distal to the first beta active region;
a first end of at least one of the one or more M(i+1) segments overlaps the first beta active region and the second alpha active region; and
a second of at least one of the one or more M(i+1) segments overlaps at least the first end correspondingly of the second beta active region and the third alpha active region.

19. The resistor-diode ladder region of claim 15, wherein:
relative to the first direction,
the second of the at least one of the one or more M(i+1) segments overlaps the second ends correspondingly of the second beta active region and the third alpha active region.

20. The resistor-diode ladder region of claim 19, wherein:
the first resistor is represented by second and third resistors coupled in parallel between the first node to the second node.
